(19) United States
(12) Patent Application Publication
(10) Pub. No.: US 2026/0182166 A1
(43) Pub. Date: Jun. 25, 2026

(54) LIGHT EMITTING DIODE DISPLAY DEVICE AND DISPLAY PANEL

(71) Applicant: LG Display Co., Ltd., Seoul (KR)

(72) Inventors: Do-Hun KWAK, Paju-si (KR); Sung-Jin LEE, Paju-si (KR)

(73) Assignee: LG Display Co., Ltd., Seoul (KR)

(21) Appl. No.: 19/387,341

(22) Filed: Nov. 12, 2025

(30) Foreign Application Priority Data
Dec. 23, 2024 (KR) 10-2024-0193961

(51) Int. Cl. H10K 59/124; H10H 29/37; H10H 29/41; H10H 29/49; H10H 29/80; H10H 29/85; H10K 59/122; H10K 59/131; H10K 59/38; H10K 59/80; H10K 102/00; H10K 102/10

(52) U.S. Cl. CPC H10K 59/124; H10H 29/37; H10H 29/41; H10H 29/49; H10H 29/8323; H10H 29/8421; H10H 29/8517; H10K 59/122; H10K 59/131; H10K 59/38; H10K 59/8051; H10K 59/878; H10K 2102/102; H10K 2102/103; H10K 2102/351

(57) ABSTRACT

A light emitting diode display device and a display panel included therein are discussed. The light emitting diode display device includes a substrate having a pixel with an emission area and a non-emission area, a first insulating layer disposed on the substrate, a step compensation pattern disposed on the first insulating layer and corresponding to the emission area, a second insulating layer covering the step compensation pattern, a first electrode disposed on the second insulating layer and corresponding to the step compensation pattern, and a pixel definition layer disposed on the second insulating layer and in the non-emission area. The pixel definition layer can cover an edge of the first electrode and has an opening corresponding to to a center area of the first electrode. The step compensation pattern has a shape that is the same as the shape of the opening of the pixel definition layer.

### CROSS-REFERENCE TO RELATED APPLICATIONS

The present application claims priority to Korean Patent Application No. 10-2024-0193961, filed in the Republic of Korea on Dec. 23, 2024, which is hereby expressly incorporated by reference in its entirety.

### BACKGROUND

### Technical Field

The present disclosure relates to a display device, and more specifically, to a display device being capable of preventing or minimizing a light leakage at an edge and providing high quality image.

### Discussion of the Related Art

Recently, a need for flat panel display devices to have small occupied area has increased. Among the flat panel display devices, a technology of a light emitting display device is rapidly developed.

The light emitting diode display device can be classified into an organic light emitting diode display device and an inorganic light emitting diode display device.

For example, in the organic light emitting diode (OLED) display device, holes from an anode and electrons from a cathode are combined to generate an exciton in an organic light emitting layer, and the exciton is transformed from an excited state to a ground state. As a result, the light is emitted from the OLED.

### SUMMARY OF THE DISCLOSURE

The present disclosure is directed to a light emitting diode display device that substantially obviates one or more of the problems associated with the limitations and disadvantages of the related conventional art.

An object of the present disclosure is to provide a light emitting diode display device with improved emitting efficiency and lifespan.

An object of the present disclosure is to provide a light emitting diode display device including a first electrode with improved flatness.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure provides a light emitting diode display device comprising a substrate including a pixel, the pixel including an emission area and a non-emission area; a first insulating layer disposed on the substrate; a step compensation pattern disposed on the first insulating layer and corresponding to the emission area; a second insulating layer covering the step compensation pattern; a first electrode disposed on the second insulating layer and corresponding to the step compensation pattern; and a pixel definition layer disposed on the second insulating layer and in the non-emission area, the pixel definition layer covering an edge of the first electrode and having an opening in correspondence to a center of the first electrode, wherein the step compensation pattern has a shape being same as the opening.

Further, another aspect of the present disclosure provides a display panel comprising a substrate including a pixel, the pixel including an emission area and a non-emission area; a first insulating layer disposed on the substrate; a step compensation pattern disposed on the first insulating layer and corresponding to the emission area; a second insulating layer covering the step compensation pattern; a first electrode disposed on the second insulating layer and corresponding to the step compensation pattern; and a pixel definition layer disposed on the second insulating layer and in the non-emission area, the pixel definition layer covering an edge of the first electrode and having an opening in correspondence to a center of the first electrode, wherein the step compensation pattern has a shape being same as the opening.

It is to be understood that both the foregoing general description and the following detailed description are examples and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic view illustrating an organic light emitting display device according to one or more embodiments of the present disclosure.

FIG. 2 is a schematic circuit diagram of an organic light emitting display device according to one or more embodiments of the present disclosure.

FIG. 3 is a schematic plan view illustrating a light emitting diode display device according to a first embodiment of the present disclosure.

FIG. 4 is a schematic cross-sectional view illustrating a light emitting diode display device according to the first embodiment of the present disclosure.

FIG. 5 is a schematic plan view illustrating a light emitting diode display device according to a second embodiment of the present disclosure.

FIG. 6 is a schematic cross-sectional view illustrating a light emitting diode display device according to the second embodiment of the present disclosure.

FIG. 7 is a schematic cross-sectional view illustrating an organic light emitting diode display device according to a third embodiment of the present disclosure.

FIG. 8 is a schematic plan view illustrating a light emitting diode display device according to a fourth embodiment of the present disclosure.

FIG. 9 is a schematic cross-sectional view illustrating a light emitting diode display device according to the fourth embodiment of the present disclosure.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described.

The expression such as “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present invention, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

The area, length, or thickness of each component described in the specification is illustrated for convenience of explanation, and the present invention is not necessarily limited to the area and thickness of the illustrated component.

It will be understood that, although the terms such as “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure. Further, the term “can” fully encompasses all the meanings and coverages of the term “may” and vice versa.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Without specific description, a transistor constituting the pixel circuit of the present disclosure can include at least one of an oxide thin film transistor (Oxide TFT), an amorphous silicon TFT (a-Si TFT), and a low temperature poly silicon (LTPS) TFT.

Reference will now be made in detail to some of the examples and various embodiments of the present disclosure, which are illustrated in the accompanying drawings. All the components of each display device and each display panel according to all embodiments of the present disclosure are operatively coupled and configured.

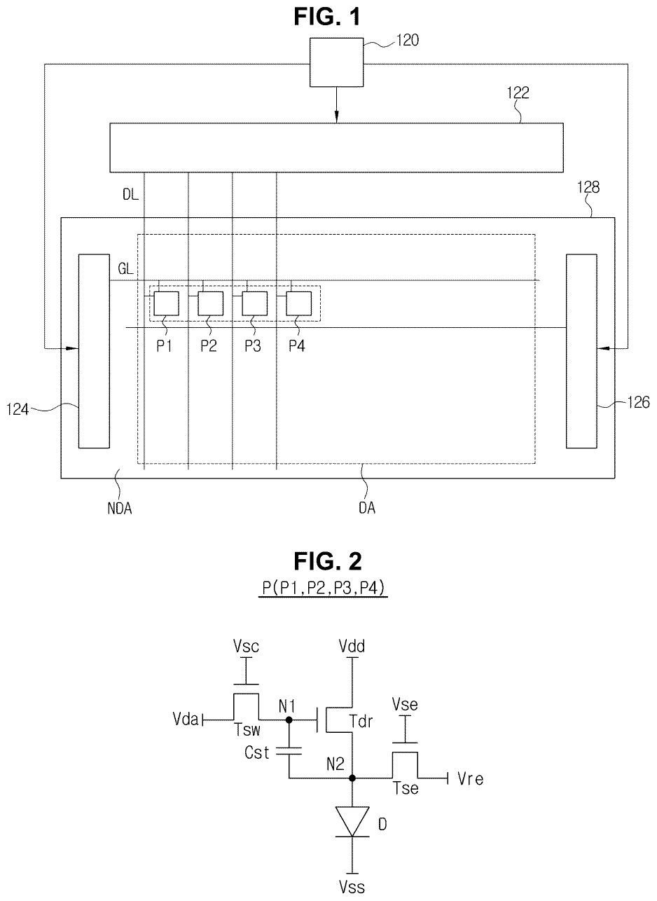

FIG. 1 is a schematic view illustrating a light emitting diode display device according to one or more embodiments of the present disclosure.

The light emitting diode display device can be an organic light emitting diode (OLED) display device including an OLED, which uses an organic emitting material, or an inorganic light emitting diode display device including an inorganic light emitting diode, which uses an inorganic emitting material.

Referring to FIG. 1, the light emitting diode display device according to an embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 122, and transmits the gate control signal to the first and second gate driving units 124 and 126.

The data driving unit 122 generates a data signal (a data voltage) Vda (of FIG. 2) using the image data and the data control signal transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal transmitted from the timing controlling unit 120 and applies the gate signal Vsc and Vse to a gate line GL of the display panel 128.

The first and second gate driving units 124 and 126 can have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the embodiment of FIG. 1, one gate driving unit can be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixels P, a plurality of gate lines GL and a plurality of data lines DL in the display area DA.

Each of the plurality of pixels P is one of first, second, third and fourth pixels P1, P2, P3 and P4, and the gate line GL and the data line DL cross each other to define the first, second, third and fourth pixels P1, P2, P3 and P4. Each of the first, second, third and fourth pixels P1, P2, P3 and P4 is connected to the gate line GL and the data line DL. For example, the first, second, third and fourth pixels P1, P2, P3 and P4 and SP4 can correspond to red, green, blue and white colors, respectively.

Each of the first, second, third and fourth pixels P1, P2, P3 and P4 can include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode D (of FIG. 2).

FIG. 2 is a schematic circuit diagram of an organic light emitting display device according to one or more embodiments of the present disclosure.

Referring to FIG. 2, each of the first, second, third and fourth pixels P1, P2, P3 and P4 of the display panel 128 of the light emitting diode display device according to an embodiment of the present disclosure includes a switching transistor Tsw, a driving transistor Tdr, a sensing transistor Tse, a storage capacitor Cst and a light emitting diode D. For example, each pixel of the organic light emitting display device of the present disclosure can have the configuration of FIG. 2.

Although each of the first, second, third and fourth pixels P1, P2, P3 and P4 has a 3TIC structure having three transistors and one storage capacitor in the embodiment of FIG. 2, each of the first, second, third and fourth pixels P1, P2, P3 and P4 can have one of a 6TIC structure having six transistors and one storage capacitor, a 7T1C structure having seven transistors and one storage capacitor and a 8TIC structure having eight transistors and one storage capacitor in another embodiment.

Although the switching transistor Tsw, the driving transistor Tdr and the sensing transistor Tse can have a negative type in the embodiment of FIG. 2, at least one of the switching transistor Tsw, the driving transistor Tdr and the sensing transistor Tse can have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode D emits a light of a luminance proportional to a current of the driving transistor Tdr.

An anode of the light emitting diode D is connected to the second node N2, and a cathode of the light emitting diode D is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode D constitute the second node N2.

The light emitting diode D can display an image having a luminance corresponding to the image data RGB according to a driving of pixel circuits of the first, second, third and fourth pixels P1, P2, P3 and P4.

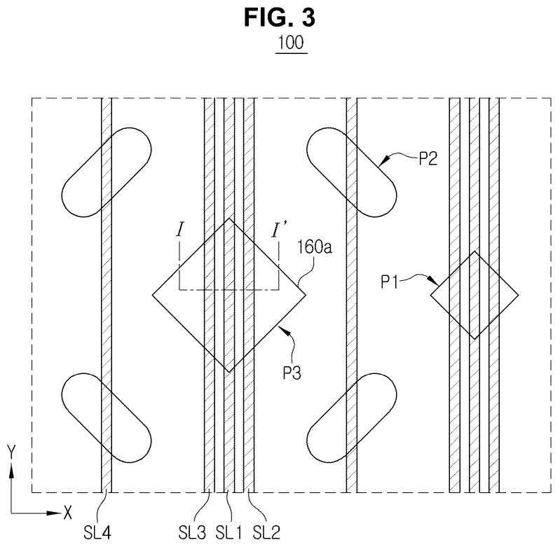

FIG. 3 is a schematic plan view illustrating a light emitting diode display device according to a first embodiment of the present disclosure.

Referring to FIG. 3, a light emitting diode display device 100 according to the first embodiment of the present disclosure includes a first pixel P1, a second pixel P2, a third pixel P3, first to third signal lines SL1, SL2 and SL3, which cross the first and third pixels P1 and P3 and extend along one direction, and a fourth signal line SL4, which crosses the second pixel P2 and extending to be parallel to the first to third signal lines SL1, SL2 and SL3.

For example, the first pixel P1 can be a red pixel, the second pixel P2 can be a green pixel, and the third pixel P3 can be a blue pixel. The light emitting diode display device 100 can further include a fourth pixel being a white pixel.

The first and third pixels P1 and P3 can have the same shape, and the second pixel P2 can have a different shape from the first and third pixels P1 and P3. However, a shape of the first to third pixels P1, P2 and P3 is not limited.

An area of the third pixel P3 can be greater than that of each of the first and second pixels P1 and P2, and an area of the first pixel P1 can be equal to or smaller than that of the second pixel P2. However, an area of the first to third pixels P1, P2 and P3 is not limited.

The first and third pixels P1 and P3 are alternately arranged along a first direction X. The second pixel P2 is spaced apart from a pixel column including the first and third pixel P1 and P3 in a second direction Y and arranged along the first direction X. The second direction Y crosses the first direction X. The second direction Y can be perpendicular to the first direction X.

A first electrode 160a of a light emitting diode D (of FIG. 2) is arranged in an island shape in each of the first to third pixels P1, P2 and P3.

Each of the first to fourth signal lines SL1, SL2, SL3 and SL4 extends along the second direction Y and are spaced apart from each other in the first direction X. The first signal line SL1 is positioned between the second and third signal lines SL2 and SL3, and the fourth signal line SL4 is positioned at one side of the second signal lines SL2 and at one side of the third signal line SL3.

The first signal line SL1 can be a high level signal line for applying the high level signal Vdd (of FIG. 2), and each of the second and third signal lines SL2 and SL3 can be a date line DL (of FIG. 1). The fourth signal lines SL4 can be a reference signal line for applying the reference signal Vre (of FIG. 2).

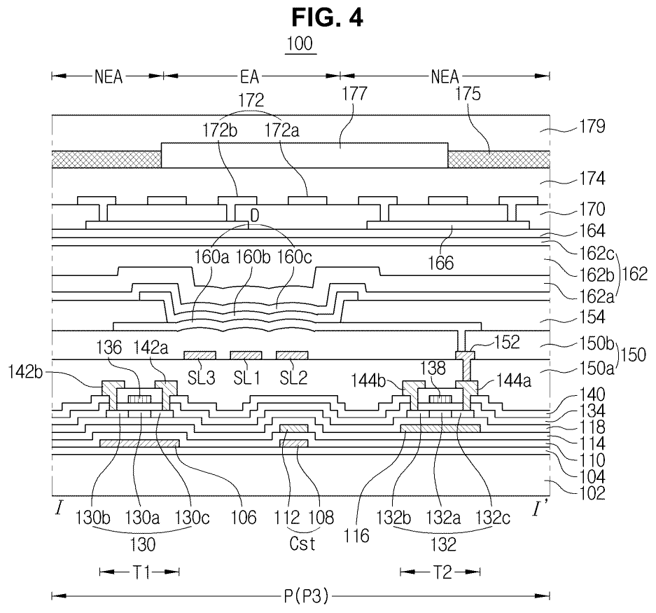

FIG. 4 is a schematic cross-sectional view illustrating a light emitting diode display device according to the first embodiment of the present disclosure. Particularly, FIG. 4 shows a cross-sectional view taken along the line I-I′ of FIG. 3.

Referring to FIG. 4, the light emitting diode display device 100 includes a substrate 102 including a pixel P, a pixel circuit layer disposed over the substrate 102 and including first and second transistors T1 and T2, a first insulating layer 150a disposed over the pixel circuit layer, first to third signal lines SL1, SL2 and SL3 disposed over the first insulating layer 150a, a second insulating layer 150b covering the first to third signal lines SL1, SL2 and SL3 and a light emitting diode D disposed on the second insulating layer 150b. The pixel circuit layer corresponds to the pixel P.

A plurality of pixels P are defined on the substrate 102. The pixel P includes an emission area EA and a non-emission area NEA. The non-emission area NEA can surround the emission area EA. The substrate 102 can be a glass substrate or a plastic substrate.

In an embodiment of the present disclosure, the substrate 102 can have a triple-layered structure including a first polyimide (PI) layer, a second P1 layer and an interlayer inorganic layer between the first and second P1 layers.

A first buffer layer 104 is disposed on the substrate 102. The external moisture and/or oxygen can be blocked by the first buffer layer 104.

A first light shielding pattern 106 is disposed on the first buffer layer 104. The light from a side of the substrate 102 can be blocked by the first light shielding pattern 106.

A first capacitor electrode 108 is disposed on the first buffer layer 104. The first capacitor electrode 108 can be spaced apart from the first light shielding pattern 106.

A second buffer layer 110 is disposed over the substrate 102 to cover the first light shielding pattern 106 and the first capacitor electrode 108. The external moisture and/or oxygen can be blocked by the second buffer layer 110.

A second capacitor electrode 112 corresponding to the first capacitor electrode 108 is disposed on the second buffer layer 110. The second capacitor electrode 112 overlaps the first capacitor electrode 108. The first capacitor electrode 108, the second buffer layer 110 and the second capacitor electrode 112 constitute a storge capacitor Cst.

A third buffer layer 114 is disposed over the substrate 102 to cover the second capacitor electrode 112. The external moisture and/or oxygen can be blocked by the third buffer layer 114.

A second light shielding pattern 116 is disposed on the third buffer layer 114. The light from a side of the substrate 102 can be blocked by the second light shielding pattern 116.

A fourth buffer layer 118 is disposed over the substrate 102 to cover the second light shielding pattern 116. The external moisture and/or oxygen can be blocked by the fourth buffer layer 118.

A first semiconductor layer 130 and a second semiconductor layer 132, which is spaced apart from the first semiconductor layer 130, are disposed on the fourth buffer layer 118. The first semiconductor layer 130 corresponds to the first light shielding pattern 106, and the second semiconductor layer 132 corresponds to the second light shielding pattern 116.

Each of the first and second semiconductor layers 130 and 132 can include one of a poly-crystalline semiconductor material, an amorphous semiconductor material and an oxide semiconductor material.

In an embodiment of the present disclosure, each of the first and second semiconductor layers 130 and 132 can include an oxide semiconductor material such as indium-gallium-zinc oxide (IGZO), zinc oxide (ZnO), tin oxide (SnO₂), copper oxide (CuO₂), nickel oxide (NiO), indium-tin-zinc oxide (ITZO) or indium-aluminum-zinc oxide (IAZO).

In an embodiment of the present disclosure, each of the first and second semiconductor layers 130 and 132 can include a poly-crystalline semiconductor material such as polycrystalline silicon.

In an embodiment of the present disclosure, one of the first and second semiconductor layers 130 and 132 can include the oxide semiconductor material, and the other one of the first and second semiconductor layers 130 and 132 can include the poly-crystalline semiconductor material. In this case, the first and second semiconductor layers 130 and 132 can be disposed at different layers.

The first semiconductor layer 130 includes a first channel region 130a, a first drain region 130b at one side of the first channel region 130a and a first source region 130c at the other one side of the first channel region 130a. Each of the first drain region 130b and the first source region 130c can be doped with impurities.

The second semiconductor layer 132 includes a second channel region 132a, a second drain region 132b at one side of the second channel region 132a and a second source region 132c at the other one side of the second channel region 132a. Each of the second drain region 132b and the second source region 132c can be doped with impurities.

A gate insulating layer 134 covering the first and second semiconductor layers 130 and 132 is disposed over the fourth buffer layer 118.

A first gate electrode 136 corresponding to the first channel region 130a of the first semiconductor layer 130 and a second gate electrode 138 corresponding to the second channel region 132a of the second semiconductor layer 132 are disposed on the gate insulating layer 134.

A first interlayer insulating layer 140 covering the first and second gate electrodes 136 and 138 is disposed over the gate insulating layer 134.

A first source electrode 142a, a first drain electrode 142b, a second source electrode 144a and a second drain electrode 144b spaced apart from each other are disposed on the first interlayer insulating layer 140.

The first source and drain electrodes 142a and 142b are connected to the first source and drain regions 130c and 130b of the first semiconductor layer 130 through contact holes in the first interlayer insulating layer 140 and the gate insulating layer 134, respectively. In addition, the first source electrode 142a is connected to the first capacitor electrode 108 through a contact hole in the first interlayer insulating layer 140, the gate insulating layer 134, the fourth buffer layer 118, the third buffer layer 114 and the second buffer layer 110.

The second source and drain electrodes 144a and 144b are connected to the second source and drain regions 132c and 132b of the second semiconductor layer 132 through contact holes in the first interlayer insulating layer 140 and the gate insulating layer 134, respectively. In addition, the second source electrode 144a is connected to the second capacitor electrode 112 through a contact hole in the first interlayer insulating layer 140, the gate insulating layer 134, the fourth buffer layer 118 and the third buffer layer 114.

The first semiconductor layer 130, the first gate electrode 136, the first source electrode 142a and the first drain electrode 142b constitute the first transistor T1, and the second semiconductor layer 132, the second gate electrode 138, the second source electrode 144a and the second drain electrode 144b constitute the second transistor T2. Each of the first and second transistors T1 and T2 can be a thin film transistor.

An insulating layer 150 covering the first source electrode 142a, the first drain electrode 142b, the second source electrode 144a and the second drain electrode 144b is disposed on the first interlayer insulating layer 140. Namely, the insulating layer 150 covers the first and second transistors T1 and T2.

The insulating layer 150 can include a first insulating layer 150a on the first source electrode 142a, the first drain electrode 142b, the second source electrode 144a and the second drain electrode 144b and a second insulating layer 150b on the first insulating layer 150a. For example, the first and second insulating layers 150a and 150b can be formed of the same material.

A connection electrode 152 corresponding to the second source electrode 144a is disposed on the first insulating layer 150a. The connection electrode 152 can be connected to the second source electrode 144a through a contact hole formed in the first insulating layer 150a.

The first to third signal lines SL1, SL2 and SL3 are disposed on the first insulating layer 150a. Each of the first to third signal lines SL1, SL2 and SL3 is spaced apart from the connection electrode 152. In addition, the first to third signal lines SL1, SL2 and SL3 are spaced apart from each other.

The second insulating layer 150b covers the connection electrode 152 and the first to third signal lines SL1, SL2 and SL3, and a first electrode 160a is disposed on the second insulating layer 150b. The first electrode 160a is connected to the connection electrode 152 through a contact hole formed in the second insulating layer 150b.

The first electrode 160a is separately formed in each pixel region P. The first electrode 160a can be an anode and can include a transparent conductive oxide (TCO) layer, which is formed of a conductive material, e.g., a transparent conductive oxide material, having a relatively high work function, and a reflective layer.

The transparent conductive oxide material can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer can include at least one of silver (Ag), an alloy of Ag and one of palladium (Pd), Cu, In and Nd and aluminum-palladium-copper alloy (APC). For example, the first electrode 160a can have a double-layered structure of Ag/ITO or APC/ITO or a triple-layered structure of ITO/Ag/ITO or ITO/APC/ITO.

A pixel definition layer (e.g., bank) 154 is formed on the second insulating layer 150b at a boundary of the pixel region. The pixel definition layer 154 covers an edge of the first electrode 160a and has an opening to expose a center of the first electrode 160a.

A spacer can be disposed on the pixel definition layer 154.

A light emitting layer 160b covering the first electrode 160a and the pixel definition layer 154 is disposed. The light emitting layer 160b contacts the first electrode 160a in the opening of the pixel definition layer 154. Namely, the light emitting layer 160b can be formed to contact an upper surface of the first electrode 160a and a side surface and an upper surface of the pixel definition layer 154.

For example, the light emitting layer 160b can include an emitting material layer including a host and a dopant. Alternatively, the emitting material layer of the light emitting layer 160b can include an inorganic emitting material such as a quantum dot. The light emitting layer 160b can further include at least one of a hole injection layer, a hole transporting layer, an electron blocking layer, a hole blocking layer, an electron transporting layer and an electron injection layer to have a multi-layered structure.

A second electrode 160c is formed over the substrate 102 where the light emitting layer 160b is formed. The second electrode 160c covers an entire surface of the display area. The second electrode 160c can be formed of at least one of ITO, IZO, Al, Ag, Cu, Pb, magnesium (Mg), Mo, Ti and their alloy and have a single-layered structure or a multi-layered structure. The second electrode 260c can have a thin profile (small thickness) to provide a light transmittance property (or a semi-transmittance property).

The first electrode 160a, the organic light emitting layer 160b and the second electrode 160c constitute a light emitting diode D. The light emitting diode D can emit the red, green and blue light in the red, green and blue pixel region, respectively.

In the light emitting diode display device 100, the light from the light emitting layer 160b passes through the second electrode 160c to display an image. Namely, the light emitting diode display device 100 of the present disclosure is a top-emission type display device.

An encapsulation layer (or encapsulation film) 162 is formed on the second electrode 160c to prevent or minimize penetration of moisture into the light emitting diode D. The encapsulation layer 162 can include a first inorganic insulating layer 162a, an organic insulating layer 162b and a second inorganic insulating layer 162c sequentially stacked, but it is not limited thereto.

A fifth buffer layer 164 is disposed on the encapsulation layer 162 and over an entire substrate 102. The external moisture and/or oxygen can be blocked by the fifth buffer layer 164.

A bridge pattern 166 is disposed on the fifth buffer layer 164. When the fifth buffer layer 164 is omitted, the bridge pattern 166 can be disposed directly on the encapsulation layer 162.

A second interlayer insulating layer 170 disposed on the fifth buffer layer 164 and over an entire substrate 102.

A touch electrode 172 is disposed on the second interlayer insulating layer 170. The touch electrode includes a first touch electrode 172a and a second touch electrode 172b. The first touch electrodes 172a are spaced apart from each other, and the second touch electrodes 172b is disposed between the first touch electrodes 172b. The second touch electrode 172b is connected to the bridge pattern 166 through a contact hole formed in the second interlayer insulating layer 170.

A first protection layer 174 is disposed on the first and second touch electrodes 172a and 172b and over an entire substrate 102.

A black matrix 175 is disposed on the first protection layer 174. The black matrix 175 is disposed in a boundary of the pixel region P and has an opening in correspondence to the light emitting diode D. Namely, the opening of the black matrix 175 can correspond to the opening of the pixel definition layer 154.

A color filter layer 177 corresponding to the opening of the black matrix 175 is disposed on the first protection layer 174, and a second protection layer 179 is disposed on the black matrix 175 and the color filter layer 177 and over an entire substrate 102.

In the light emitting diode display device 100 according to the first embodiment of the present disclosure, since the first to third signal lines SL1, SL2 and SL3 are disposed to cross the pixel P, a limitation to a width of the first to third signal lines SL1, SL2 and SL3 can be minimized.

However, since the first to third signal lines SL1, SL2 and SL3 are disposed under the first electrode 160a of the light emitting diode D with the second insulating layer 150b therebetween, each of the second insulating layer 150b and the first electrode 160a has an uneven (e.g., non-flat) surface by a step difference generated by the first to third signal lines SL1, SL2 and SL3. Accordingly, the emitting efficiency and/or the lifespan of the light emitting diode D and the light emitting diode display device 100 can be decreased.

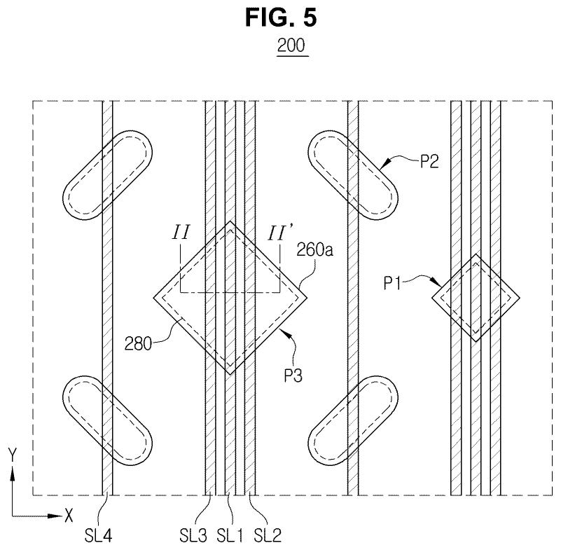

FIG. 5 is a schematic plan view illustrating a light emitting diode display device according to a second embodiment of the present disclosure.

Referring to FIG. 5, a light emitting diode display device 200 according to the second embodiment of the present disclosure includes a first pixel P1, a second pixel P2, a third pixel P3, first to third signal lines SL1, SL2 and SL3, which cross the first and third pixels P1 and P3 and extend along one direction, and a fourth signal line SL4, which crosses the second pixel P2 and extending to be parallel to the first to third signal lines SL1, SL2 and SL3.

For example, the first pixel P1 can be a red pixel, the second pixel P2 can be a green pixel, and the third pixel P3 can be a blue pixel. The light emitting diode display device 200 can further include a fourth pixel being a white pixel.

The first and third pixels P1 and P3 can have the same shape, and the second pixel P2 can have a different shape from the first and third pixels P1 and P3. However, a shape of the first to third pixels P1, P2 and P3 is not limited.

An area of the third pixel P3 can be greater than that of each of the first and second pixels P1 and P2, and an area of the first pixel P1 can be equal to or smaller than that of the second pixel P2. However, an area of the first to third pixels P1, P2 and P3 is not limited.

The first and third pixels P1 and P3 are alternately arranged along a first direction X. The second pixel P2 is spaced apart from a pixel column including the first and third pixel P1 and P3 in a second direction Y and arranged along the first direction X. The second direction Y crosses the first direction X. The second direction Y can be perpendicular to the first direction X.

The first to fourth signal lines SL1, SL2, SL3 and SL4 extend along the second direction Y and are spaced apart from each other in the first direction X. The first signal line SL1 is positioned between the second and third signal lines SL2 and SL3, and the fourth signal lines SL4 is positioned at one side of the second signal line SL2 and at one side of the third signal line SL3.

The first signal line SL1 can be a high level signal line for applying the high level signal Vdd (of FIG. 2), and each of the second and third signal lines SL2 and SL3 can be a date line DL (of FIG. 1). The fourth signal lines SL4 can be a reference signal line for applying the reference signal Vre (of FIG. 2).

In FIG. 5, the first to third signal lines SL1, SL2 and SL3 are disposed in each of the first and third pixels P1 and P3, and the fourth signal line SL4 is disposed in the second pixel P2. However, in the light emitting diode display device 200 of the present disclosure, the arrangements of the pixels P1, P2 and SP3 and the signal lines SL1, SL2, SL3 and SL4 are not limited.

A first electrode 260a of a light emitting diode D (of FIG. 2) is arranged in an island shape in each of the first to third pixels P1, P2 and P3.

In addition, a step compensation pattern 280 corresponding to the first electrode 260a is disposed in each of the first to third pixels P1, P2 and P3 and under the first electrode 260a.

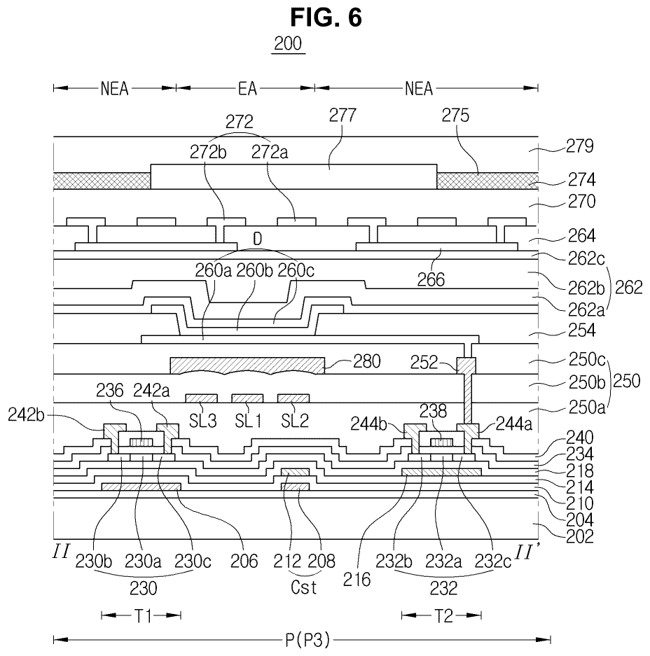

FIG. 6 is a schematic cross-sectional view illustrating a light emitting diode display device according to the second embodiment of the present disclosure. Particularly, FIG. 6 shows a cross-sectional view taken along the line II-II′ of FIG. 5.

Referring to FIG. 6, the light emitting diode display device 200 includes a substrate 202 including a pixel P, a pixel circuit layer disposed over the substrate 202 and including first and second transistors T1 and T2, a first insulating layer 250a disposed over the pixel circuit layer, first to third signal lines SL1, SL2 and SL3 disposed over the first insulating layer 250a, a second insulating layer 250b covering the first to third signal lines SL1, SL2 and SL3, a step compensation pattern 280 disposed on the second insulating layer 250b, a third insulating layer 250c disposed on the step compensation pattern 280 and a light emitting diode D disposed on the third insulating layer 250b. The pixel circuit layer corresponds to the pixel P.

A plurality of pixels P are defined on the substrate 202. The pixel P includes an emission area EA and a non-emission area NEA. The non-emission area NEA can surround the emission area EA. The substrate 202 can be a glass substrate or a plastic substrate. For example, the substrate 202 can be one of a polyimide (PI) substrate, a polyethersulfone (PES) substrate, a polyethylenenaphthalate (PEN) substrate, a polyethylene terephthalate (PET) substrate and a polycarbonate (PC) substrate.

In an embodiment of the present disclosure, the substrate 202 can have a triple-layered structure including a first polyimide (PI) layer, a second P1 layer and an interlayer inorganic layer between the first and second P1 layers.

A first buffer layer 204 is disposed on the substrate 202. The external moisture and/or oxygen can be blocked by the first buffer layer 204. For example, the first buffer layer 204 can be formed of an inorganic insulating material, e.g., silicon oxide or silicon nitride. The first buffer layer 204 can have a single-layered structure or a multi-layered structure.

A first light shielding pattern 206 is disposed on the first buffer layer 204. The light from a side of the substrate 202 can be blocked by the first light shielding pattern 206.

A first capacitor electrode 208 is disposed on the first buffer layer 204. The first capacitor electrode 208 can be spaced apart from the first light shielding pattern 206.

Each of the first light shielding pattern 204 and the first capacitor electrode 208 can be formed of the same material. For example, each of the first light shielding pattern 204 and the first capacitor electrode 208 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, each of the first light shielding pattern 204 and the first capacitor electrode 208 can have a single-layered structure or a multi-layered structure.

A second buffer layer 210 is disposed over the substrate 202 to cover the first light shielding pattern 206 and the first capacitor electrode 208. The external moisture and/or oxygen can be blocked by the second buffer layer 210. For example, the second buffer layer 210 can be formed of an inorganic insulating material, e.g., silicon oxide or silicon nitride. The second buffer layer 210 can have a single-layered structure or a multi-layered structure.

A second capacitor electrode 212 corresponding to the first capacitor electrode 208 is disposed on the second buffer layer 210. For example, the second capacitor electrode 212 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, the second capacitor electrode 212 can have a single-layered structure or a multi-layered structure.

The second capacitor electrode 212 overlaps the first capacitor electrode 208. The first capacitor electrode 208, the second buffer layer 210 and the second capacitor electrode 212 constitute a storge capacitor Cst.

A third buffer layer 214 is disposed over the substrate 202 to cover the second capacitor electrode 212. The external moisture and/or oxygen can be blocked by the third buffer layer 214. For example, the third buffer layer 214 can be formed of an inorganic insulating material, e.g., silicon oxide or silicon nitride. The third buffer layer 214 can have a single-layered structure or a multi-layered structure.

A second light shielding pattern 216 is disposed on the third buffer layer 214. The light from a side of the substrate 202 can be blocked by the second light shielding pattern 216. For example, the second light shielding pattern 216 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, the second light shielding pattern 216 can have a single-layered structure or a multi-layered structure.

A fourth buffer layer 218 is disposed over the substrate 202 to cover the second light shielding pattern 216. The external moisture and/or oxygen can be blocked by the fourth buffer layer 218. For example, the fourth buffer layer 218 can be formed of an inorganic insulating material, e.g., silicon oxide or silicon nitride. The fourth buffer layer 218 can have a single-layered structure or a multi-layered structure.

A first semiconductor layer 230 and a second semiconductor layer 232, which is spaced apart from the first semiconductor layer 230, are disposed on the fourth buffer layer 218. The first semiconductor layer 230 corresponds to the first light shielding pattern 206, and the second semiconductor layer 232 corresponds to the second light shielding pattern 216.

Each of the first and second semiconductor layers 230 and 232 can include one of a poly-crystalline semiconductor material, an amorphous semiconductor material and an oxide semiconductor material.

In an embodiment of the present disclosure, each of the first and second semiconductor layers 230 and 232 can include an oxide semiconductor material such as indium-gallium-zinc oxide (IGZO), zinc oxide (ZnO), tin oxide (SnO₂), copper oxide (CuO₂), nickel oxide (NiO), indium-tin-zinc oxide (ITZO) or indium-aluminum-zinc oxide (IAZO).

In an embodiment of the present disclosure, each of the first and second semiconductor layers 230 and 232 can include a poly-crystalline semiconductor material such as polycrystalline silicon.

In an embodiment of the present disclosure, one of the first and second semiconductor layers 230 and 232 can include the oxide semiconductor material, and the other one of the first and second semiconductor layers 230 and 232 can include the poly-crystalline semiconductor material. In this case, the first and second semiconductor layers 230 and 232 can be disposed at different layers.

The first semiconductor layer 230 includes a first channel region 230a, a first drain region 230b at one side of the first channel region 230a and a first source region 230c at the other one side of the first channel region 230a. Each of the first drain region 230b and the first source region 230c can be doped with impurities.

The second semiconductor layer 232 includes a second channel region 232a, a second drain region 232b at one side of the second channel region 232a and a second source region 232c at the other one side of the second channel region 232a. Each of the second drain region 232b and the second source region 232c can be doped with impurities.

A gate insulating layer 234 covering the first and second semiconductor layers 230 and 232 is disposed over the fourth buffer layer 218. For example, the gate insulating layer 234 can be formed of an inorganic insulating material, e.g., silicon oxide or silicon nitride. The gate insulating layer 234 can have a single-layered structure or a multi-layered structure.

A first gate electrode 236 corresponding to the first channel region 230a of the first semiconductor layer 230 and a second gate electrode 238 corresponding to the second channel region 232a of the second semiconductor layer 232 are disposed on the gate insulating layer 234. For example, each of the first and second gate electrodes 236 and 238 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, each of the first and second gate electrodes 236 and 238 can have a single-layered structure or a multi-layered structure.

A first interlayer insulating layer 240 covering the first and second gate electrodes 236 and 238 is disposed over the gate insulating layer 234. The external moisture and/or oxygen can be blocked by the first interlayer insulating layer 240. For example, the first interlayer insulating layer 240 can be formed of an inorganic insulating material, e.g., silicon oxide or silicon nitride. The first interlayer insulating layer 240 can have a single-layered structure or a multi-layered structure.

A first source electrode 242a, a first drain electrode 242b, a second source electrode 244a and a second drain electrode 244b spaced apart from each other are disposed on the first interlayer insulating layer 240.

The first source and drain electrodes 242a and 242b are connected to the first source and drain regions 230c and 230b of the first semiconductor layer 230 through contact holes in the first interlayer insulating layer 240 and the gate insulating layer 234, respectively. In addition, the first source electrode 242a is connected to the first capacitor electrode 208 through a contact hole in the first interlayer insulating layer 240, the gate insulating layer 234, the fourth buffer layer 218, the third buffer layer 214 and the second buffer layer 210.

The second source and drain electrodes 244a and 244b are connected to the second source and drain regions 232c and 232b of the second semiconductor layer 232 through contact holes in the first interlayer insulating layer 240 and the gate insulating layer 234, respectively. In addition, the second source electrode 244a is connected to the second capacitor electrode 212 through a contact hole in the first interlayer insulating layer 240, the gate insulating layer 234, the fourth buffer layer 218 and the third buffer layer 214.

The first source electrode 242a, the first drain electrode 242b, the second source electrode 244a and the second drain electrode 244b can be disposed on the same layer and formed of the same material. For example, each of the first source electrode 242a, the first drain electrode 242b, the second source electrode 244a and the second drain electrode 244b can be formed of a metallic material, e.g., molybdenum (Mo), aluminum (Al) chromium (Cr), gold (Au), titanium (Ti), nickel (Ni), neodymium (Nd), copper (Cu) or their alloys. In addition, each of the first source electrode 242a, the first drain electrode 242b, the second source electrode 244a and the second drain electrode 244b can have a single-layered structure or a multi-layered structure.

The first semiconductor layer 230, the first gate electrode 236, the first source electrode 242a and the first drain electrode 242b constitute the first transistor T1, and the second semiconductor layer 232, the second gate electrode 238, the second source electrode 244a and the second drain electrode 244b constitute the second transistor T2. Each of the first and second transistors T1 and T2 can be a thin film transistor.

In FIG. 6, the first gate electrode 236, the first source electrode 242a and the first drain electrode 242b are disposed over the first semiconductor layer 230, and the second gate electrode 238, the second source electrode 244a and the second drain electrode 244b are disposed over the second semiconductor layer 232. Namely, each of the first and second transistors T1 and T2 has a coplanar structure. Alternatively, in each of the first and second transistors T1 and T2, the gate electrode can be disposed under the semiconductor layer, and the source and drain electrodes can be disposed over the semiconductor layer. Namely, each of the first and second transistors T1 and T2 can have an inverted staggered structure.

An insulating layer 250 covering the first source electrode 242a, the first drain electrode 242b, the second source electrode 244a and the second drain electrode 244b is disposed on the first interlayer insulating layer 240. Namely, the insulating layer 250 covers the first and second transistors T1 and T2.

The insulating layer 250 can include a first insulating layer 250a on the first source electrode 242a, the first drain electrode 242b, the second source electrode 244a and the second drain electrode 244b, a second insulating layer 250b on the first insulating layer 250a and a third insulating layer 250c on the second insulating layer 250b. For example, the first and second insulating layers 250a and 250b can be formed of the same material. Each of the first to third insulating layers 250a, 250b and 250c can be formed of an organic insulating material, e.g., photo-acryl or benzocyclobutene (BCB). The first to third insulating layers 250a, 250b and 250c can be formed of the same material.

The first to third signal lines SL1, SL2 and SL3 are disposed on the first insulating layer 250a. The first to third signal lines SL1, SL2 and SL3 extends along the second direction Y and are spaced apart from each other in the first direction X. The first signal line SL1 can be a high level signal line for applying the high level signal Vdd (of FIG. 2), and each of the second and third signal lines SL2 and SL3 can be a data line DL (of FIG. 1).

Each of the first to third signal lines SL1, SL2 and SL3 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, each of the first to third signal lines SL1, SL2 and SL3 can have a single-layered structure or a multi-layered structure.

The second insulating layer 250b covering the first to third signal lines SL1, SL2 and SL3 is disposed on the first insulating layer 250a.

A connection electrode 252 corresponding to the second source electrode 244a is disposed on the second insulating layer 250b. The connection electrode 252 can be connected to the second source electrode 244a through a contact hole formed in the second insulating layer 250b.

In addition, the step compensation pattern 280 is disposed on the second insulating layer 250b. The step compensation pattern 280 corresponds to the first to third signal lines SL1, SL2 and SL3 and is spaced apart from the connection pattern 252.

The pixel P includes an emission area and a non-emission area surrounding the emission area. The step compensation pattern 280 is disposed in the emission area and has an island shape. The step compensation pattern 280 has an uneven bottom surface and an even top surface.

The first to third signal lines SL1, SL2 and SL3 are disposed to correspond to the pixel P so that the second insulating layer 250b has an uneven surface. Namely, the step difference by the first to third signal lines SL1, SL2 and SL3 is reflected onto the second insulating layer 250b so that the flatness of the second insulating layer 250b is degraded.

In the light emitting diode display device 200 of the present disclosure, the step compensation pattern 280 corresponding to the first to third signal lines SL1, SL2 and SL3 covers the uneven surface of the second insulating layer 250b so that the unevenness of the second insulating layer 250b can be compensated.

In an embodiment of the present disclosure, each of the first to third signal lines SL1, SL2 and SL3 can have a first thickness, and the step compensation pattern 280 can have a second thickness being greater than the first thickness.

Each of the connection electrode 252 and the step compensation pattern 280 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, each of the connection electrode 252 and the step compensation pattern 280 can have a single-layered structure or a multi-layered structure.

In FIG. 6, the connection electrode 252 is disposed on the second insulating layer 250b. Alternatively, the connection electrode 252 can be disposed on the first insulating layer 250a and under the second insulating layer 250b.

The third insulating layer 250c is disposed on the connection electrode 252 and the step compensation pattern 280, and the first electrode 260a is disposed on the third insulating layer 250c. The first electrode 260a is connected to the connection electrode 252 through a contact hole formed in the third insulating layer 250c.

The first electrode 260a is separately formed in each pixel region P. The first electrode 260a can be an anode and can include a transparent conductive oxide (TCO) layer, which is formed of a conductive material, e.g., a transparent conductive oxide material, having a relatively high work function, and a reflective layer.

The transparent conductive oxide material can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer can include at least one of silver (Ag), an alloy of Ag and one of palladium (Pd), Cu, In and Nd and aluminum-palladium-copper alloy (APC). For example, the first electrode 260a can have a double-layered structure of Ag/ITO or APC/ITO or a triple-layered structure of ITO/Ag/ITO or ITO/APC/ITO.

A pixel definition layer (e.g., bank) 254 is formed on the third insulating layer 250c at a boundary of the pixel region. The pixel definition layer 254 is disposed in the non-emission area. The pixel definition layer 254 covers an edge of the first electrode 260a and has an opening to expose a center of the first electrode 260a. For example, the pixel definition layer 254 can be formed of an organic insulating material, e.g., photo-acryl, BCB or P1.

The step compensation pattern 280 can have substantially the same shape. For example, the step compensation pattern 280 can have the same shape as the opening of the pixel definition layer 254. The step compensation pattern 280 can have an area being larger than the opening of the pixel definition layer 254 and smaller than the first electrode 260a.

In the light emitting diode display device 200 according to the second embodiment of the present disclosure, the step difference by the first to third signal lines SL1, SL2 and SL3 is compensated by the step compensation pattern 280 so that at least a portion of the first electrode 260a, e.g., the first electrode 260a in the opening of the pixel definition layer 254, has an even (e.g., flat) surface. Accordingly, the decrease of the emitting efficiency and/or the lifespan of the light emitting diode display device 200 can be minimized or prevented.

A spacer can be disposed on the pixel definition layer 254. The spacer can have an area being smaller than the pixel definition layer 254.

A light emitting layer 260b covering the first electrode 260a and the pixel definition layer 254 is disposed. The light emitting layer 260b contacts the first electrode 260a in the opening of the pixel definition layer 254. Namely, the light emitting layer 260b can be formed to contact an upper surface of the first electrode 260a and a side surface and an upper surface of the pixel definition layer 254.

For example, the light emitting layer 260b can include an emitting material layer including a host and a dopant. Alternatively, the emitting material layer of the light emitting layer 260b can include an inorganic emitting material such as a quantum dot. The light emitting layer 260b can further include at least one of a hole injection layer, a hole transporting layer, an electron blocking layer, a hole blocking layer, an electron transporting layer and an electron injection layer to have a multi-layered structure.

A second electrode 260c is formed over the substrate 202 where the light emitting layer 260b is formed. The second electrode 260c covers an entire surface of the display area. The second electrode 260c can be formed of at least one of ITO, IZO, Al, Ag, Cu, Pb, magnesium (Mg), Mo, Ti and their alloy and have a single-layered structure or a multi-layered structure. The second electrode 260c can have a thin profile (small thickness) to provide a light transmittance property (or a semi-transmittance property).

The first electrode 260a, the organic light emitting layer 260b and the second electrode 260c constitute a light emitting diode D. The light emitting diode D can emit the red, green and blue light in the red, green and blue pixel region, respectively.

In the light emitting diode display device 200, the light from the light emitting layer 260b passes through the second electrode 260c to display an image. Namely, the light emitting diode display device 200 of the present disclosure is a top-emission type display device.

In an embodiment of the present disclosure, the first electrode 260a can be a transparent electrode. Namely, the first electrode 260a can have a single-layered structure of the transparent conductive oxide layer.

In this case, the step compensation pattern 280 under the first electrode 260a acts as a reflection layer to the light passing through the first electrode 260a. Accordingly, although the first electrode 260a has a single-layered structure of the transparent conductive oxide layer in the top-emission type light emitting diode display device 200, the efficiency of the light emitting diode display device 200 is not decreased.

In addition, since the first electrode 260a has a single-layered structure of the transparent conductive oxide layer, a process defect problem, which can occur in the pattern process of the first electrode 260a, can be prevented. For example, in the light emitting diode device 200 including the first electrode 260a with an ITO/Ag/ITO structure or an ITO/APC/ITO structure, after a transparent conductive oxide material layer, a reflective layer and a transparent conductive oxide material layer are sequentially stacked, a mask process is performed to form the first electrode 260a. There can be a process defect in an etching process for different materials so that a shortage problem between the first electrodes 260a in adjacent pixels and/or a current leakage problem in adjacent pixels can occur.

However, in the light emitting diode display device 200 of the present disclosure, the step compensation pattern 280 acts as a reflection layer and the first electrode 260a has a single-layered structure of the transparent conductive oxide layer. Accordingly, the light emitting diode display device 200 of the present disclosure can provide improved emitting efficiency and/or the lifespan without the above problems.

An encapsulation layer (or encapsulation film) 262 is formed on the second electrode 260c to prevent or minimize penetration of moisture into the light emitting diode D. The encapsulation layer 262 can include a first inorganic insulating layer 262a, an organic insulating layer 262b and a second inorganic insulating layer 262c sequentially stacked, but it is not limited thereto.

For example, each of the first and second inorganic insulating layers 262a and 262c can be formed of an inorganic insulating material, e.g., silicon oxide or silicon nitride, and the organic insulating layer 262b can be formed of an organic insulating material, e.g., acryl resin, epoxy resin, phenolic resin, polyamide resin or polyimide resin.

A fifth buffer layer 264 is disposed on the encapsulation layer 262 and over an entire substrate 202. The external moisture and/or oxygen can be blocked by the fifth buffer layer 264. For example, the fifth buffer layer 264 can be formed of an inorganic insulating material, e.g., silicon oxide or silicon nitride. The fifth buffer layer 264 can have a single-layered structure or a multi-layered structure.

A bridge pattern 266 is disposed on the fifth buffer layer 264. When the fifth buffer layer 264 is omitted, the bridge pattern 266 can be disposed directly on the encapsulation layer 262. For example, the bridge pattern 266 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, the bridge pattern 266 can have a single-layered structure or a multi-layered structure.

A second interlayer insulating layer 270 disposed on the fifth buffer layer 264 and over an entire substrate 202. For example, the second interlayer insulating layer 270 can be formed of an inorganic insulating material, e.g., silicon oxide or silicon nitride, or an organic insulating material. e.g., photo-acryl or BCB. The second interlayer insulating layer 270 can have a single-layered structure or a multi-layered structure.

A touch electrode 272 is disposed on the second interlayer insulating layer 270. The touch electrode includes a first touch electrode 272a and a second touch electrode 272b. The first touch electrodes 272a are spaced apart from each other, and the second touch electrodes 272b is disposed between the first touch electrodes 272b. The second touch electrode 272b is connected to the bridge pattern 266 through a contact hole formed in the second interlayer insulating layer 270.

For example, each of the first touch electrodes 272a and the second touch electrodes 272b can be formed of one of ITO, IZO, Al, Ag, Cu, Pb, Mg, Mo, Ti and their alloys. In addition, each of the first touch electrodes 272a and the second touch electrodes 272b can have a single-layered structure or a multi-layered structure.

A first protection layer 274 is disposed on the first and second touch electrodes 272a and 272b and over an entire substrate 202. The first protection layer 274 can be formed of an inorganic insulating material, e.g., silicon oxide or silicon nitride, or an organic insulating material. e.g., photo-acryl or BCB. The first protection layer 274 can have a single-layered structure or a multi-layered structure.

A black matrix 275 is disposed on the first protection layer 274. The black matrix 275 is disposed in a boundary of the pixel region P and has an opening in correspondence to the light emitting diode D. Namely, the opening of the black matrix 275 can correspond to the opening of the pixel definition layer 254.

The opening of the black matrix 275 can have an area being larger than the opening of the pixel definition layer 254. For example, the pixel definition layer 254 can have a first width, and the black matrix 275 can have a second width being smaller than the first width. When the area of the opening of the black matrix 275 is equal to or smaller than that of the opening of the pixel definition layer 254, the viewing angle of the light emitting diode display device 200 can be decreased.

A color filter layer 277 corresponding to the opening of the black matrix 275 is disposed on the first protection layer 274. The color filter layer 277 can include a red color filter corresponding to the red pixel, a green color filter corresponding to the green pixel and a blue color filter corresponding to the blue pixel.

The color filter layer 277 can include an organic material and a color particle (e.g., a color pigment or a color dye). For example, the organic material can be selected from the group consisting of polymethylmethacrylate, polycarbonate, polyacrylate, polyurethane, epoxy, polyester and polyimide, but it is not limited thereto.

A second protection layer 279 is disposed on the black matrix 275 and the color filter layer 277 and over an entire substrate 202. For example, the second protection layer 279 can be formed of an inorganic insulating material, e.g., silicon oxide or silicon nitride. The second protection layer 279 can have a single-layered structure or a multi-layered structure.

In the light emitting diode display device 200 according to the second embodiment of the present disclosure, since the first to third signal lines SL1, SL2 and SL3 are disposed to cross the pixel P, a limitation to a width of the first to third signal lines SL1, SL2 and SL3 can be minimized.

In addition, the light emitting diode display device 200 includes the step compensation pattern 280 covering the first, second and third signal lines SL1, SL2 and SL3 and disposed under the first electrode 260a, the flatness of the first electrode 260a can be improved. Accordingly, the decrease of the emitting efficiency and/or the lifespan of the light emitting diode display device 200 resulted from the unevenness of the first electrode 260a can be minimized or prevented.

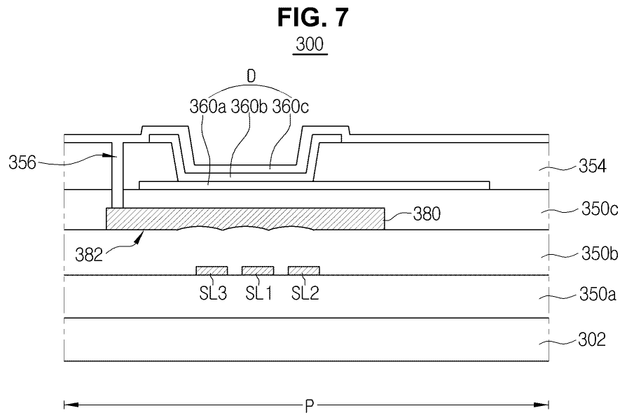

FIG. 7 is a schematic cross-sectional view illustrating an organic light emitting diode display device according to a third embodiment of the present disclosure and shows a cross-sectional view taken along the line II-II′ of FIG. 5.

For convenience of explanation, the configuration between the substrate 302 and the first insulating layer 350c, the configuration above the second electrode 360c, and the connection electrode 252 (of FIG. 6) are not illustrated.

Referring to FIG. 7, the light emitting diode display device 300 includes a substrate 302 including a pixel P, a first insulating layer 350a disposed over the substrate 302, first to third signal lines SL1, SL2 and SL3 disposed over the first insulating layer 350a, a second insulating layer 350b covering the first to third signal lines SL1, SL2 and SL3, a step compensation pattern 380 disposed on the second insulating layer 350b, a third insulating layer 350c disposed on the step compensation pattern 380 and a light emitting diode D disposed on the third insulating layer 250b and including a second electrode 360c, which is electrically connected to the step compensation pattern 380.

The first to third signal lines SL1, SL2 and SL3 are disposed on the first insulating layer 350a. The first to third signal lines SL1, SL2 and SL3 extends along the second direction Y and are spaced apart from each other. The first signal line SL1 can be a high level signal line for applying the high level signal Vdd (of FIG. 2), and each of the second and third signal lines SL2 and SL3 can be a data line DL (of FIG. 1).

The second insulating layer 350b covering the first to third signal lines SL1, SL2 and SL3 is disposed on the first insulating layer 350a.

The step compensation pattern 380 is disposed on the second insulating layer 350b. The step compensation pattern 380 corresponds to and covers the first to third signal lines SL1, SL2 and SL3 and is spaced apart from the connection pattern 252 (of FIG. 6).

The first to third signal lines SL1, SL2 and SL3 are disposed to correspond to the pixel P so that the second insulating layer 350b has an uneven surface. Namely, the step difference by the first to third signal lines SL1, SL2 and SL3 is reflected onto the second insulating layer 350b so that the flatness of the second insulating layer 350b is degraded.

In the light emitting diode display device 300 of the present disclosure, the step compensation pattern 380 corresponding to the first to third signal lines SL1, SL2 and SL3 covers the uneven surface of the second insulating layer 350b so that the unevenness of the second insulating layer 350b can be compensated.

The step compensation pattern 380 includes an extending portion 382 disposed under the pixel definition layer 354. Namely, at least one end of the step compensation pattern 380 extends below pixel definition layer 354 to form the extending portion 382. The extending portion 382 protrudes from the first electrode 360a. For example, the extending portion 382 extends beyond the edge of the first electrode 360a under the first electrode 360a.

In an embodiment of the present disclosure, each of the first to third signal lines SL1, SL2 and SL3 can have a first thickness, and the step compensation pattern 380 can have a second thickness being greater than the first thickness.

The step compensation pattern 380 can be formed of a metallic material, e.g., molybdenum (Mo), aluminum (Al) chromium (Cr), gold (Au), titanium (Ti), nickel (Ni), neodymium (Nd), copper (Cu) or their alloys. In addition, the step compensation pattern 380 can have a single-layered structure or a multi-layered structure.

The third insulating layer 350c is disposed on the step compensation pattern 380, and the first electrode 360a is disposed on the third insulating layer 350c.

The first electrode 360a is separately formed in each pixel region P. The first electrode 260a can be an anode and can include a transparent conductive oxide (TCO) layer, which is formed of a conductive material, e.g., a transparent conductive oxide material, having a relatively high work function, and a reflective layer.

In an embodiment of the present disclosure, the first electrode 360a can be a transparent electrode 360a. Namely, the first electrode 360a can have a single-layered structure of the transparent conductive oxide layer.

The step compensation pattern 380 under the first electrode 360a acts as a reflection layer to the light passing through the first electrode 360a. Accordingly, although the first electrode 360a has a single-layered structure of the transparent conductive oxide layer in the top-emission type light emitting diode display device 300, the efficiency of the light emitting diode display device 300 is not decreased.

A pixel definition layer (e.g., bank) 354 is formed on the third insulating layer 350c at a boundary of the pixel region. The pixel definition layer 354 covers an edge of the first electrode 360a and has an opening to expose a center of the first electrode 360a.

The step compensation pattern 380 can have substantially the same shape. For example, the step compensation pattern 380 can have the same shape as the opening of the pixel definition layer 354. The step compensation pattern 380 can have an area being larger than the opening of the pixel definition layer 354 and smaller than the first electrode 260a.

In the light emitting diode display device 300 according to the third embodiment of the present disclosure, the step difference by the first to third signal lines SL1, SL2 and SL3 is compensated by the step compensation pattern 380 so that at least a portion of the first electrode 360a, e.g., the first electrode 360a in the opening of the pixel definition layer 354, has an even (e.g., flat) surface. Accordingly, the decrease of the emitting efficiency and/or the lifespan of the light emitting diode display device 300 can be minimized or prevented.

An auxiliary contact hole 356 corresponding to the extending portion 382 of the step compensation layer 380 is formed in the pixel definition layer 354 and the third insulating layer 350c. Namely, the extending portion 382 of the step compensation layer 380 is exposed through the auxiliary contact hole 356 in the pixel definition layer 354 and the third insulating layer 350c.

A light emitting layer 360b covering the first electrode 360a and the pixel definition layer 354 is disposed. The light emitting layer 360b contacts the first electrode 360a in the opening of the pixel definition layer 354. Namely, the light emitting layer 360b can be formed to contact an upper surface of the first electrode 360a and a side surface and an upper surface of the pixel definition layer 354.

For example, the light emitting layer 360b can include an emitting material layer including a host and a dopant. Alternatively, the emitting material layer of the light emitting layer 360b can include an inorganic emitting material such as a quantum dot. The light emitting layer 360b can further include at least one of a hole injection layer, a hole transporting layer, an electron blocking layer, a hole blocking layer, an electron transporting layer and an electron injection layer to have a multi-layered structure.

A second electrode 360c is formed over the substrate 302 where the light emitting layer 360b is formed. The second electrode 360c covers an entire surface of the display area. The second electrode 360c can be formed of at least one of ITO, IZO, Al, Ag, Cu, Pb, magnesium (Mg), Mo, Ti and their alloy and have a single-layered structure or a multi-layered structure. The second electrode 360c can have a thin profile (small thickness) to provide a light transmittance property (or a semi-transmittance property).

The second electrode 360c is disposed on the pixel definition layer 354 and is connected to the extending portion 382 of the step compensation layer 380 through the auxiliary contact hole 356 in the pixel definition layer 354 and the third insulating layer 350c.

Since the second electrode 360c has thin profile and is formed on an entire surface of the substrate 202, there can be a voltage drop problem in the second electrode 360c according to a position of the pixel. However, in the light emitting diode display device 300 according to the third embodiment of the present disclosure, the extending portion 382 as a part of the step compensation pattern 380, which is provided to enhance the flatness of the first electrode 360a, is connected to the second electrode 360c, the resistance of the second electrode 260c is reduced so that the voltage drop problem can be minimized or prevented.

In the light emitting diode display device 300 according to the third embodiment of the present disclosure, since the first to third signal lines SL1, SL2 and SL3 are disposed to cross the pixel P, a limitation to a width of the first to third signal lines SL1, SL2 and SL3 can be minimized.

In addition, the light emitting diode display device 300 includes the step compensation pattern 380 covering the first, second and third signal lines SL1, SL2 and SL3 and disposed under the first electrode 360a, the flatness of the first electrode 360a can be improved. Accordingly, the decrease of the emitting efficiency and/or the lifespan of the light emitting diode display device 300 resulted from the unevenness of the first electrode 360a can be minimized or prevented.

Moreover, in the light emitting diode display device 300 according to the third embodiment of the present disclosure, the extending portion 382 of the step compensation pattern 380 is connected to the second electrode 360c, the resistance of the second electrode 260c is reduced so that the voltage drop problem can be minimized or prevented.

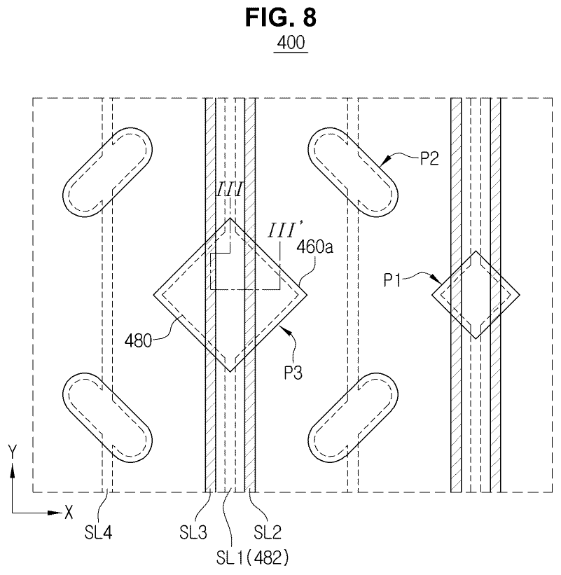

FIG. 8 is a schematic plan view illustrating a light emitting diode display device according to a fourth embodiment of the present disclosure.

Referring to FIG. 8, a light emitting diode display device 200 according to the second embodiment of the present disclosure includes a first pixel P1, a second pixel P2, a third pixel P3, second and third signal lines SL2 and SL3, which cross the first and third pixels P1 and P3 and extend along one direction, and a fourth signal line SL4, which crosses the second pixel P2 and extending to be parallel to the second and third signal lines SL2 and SL3.

For example, the first pixel P1 can be a red pixel, the second pixel P2 can be a green pixel, and the third pixel P3 can be a blue pixel. The light emitting diode display device 400 can further include a fourth pixel being a white pixel.

The first and third pixels P1 and P3 can have the same shape, and the second pixel P2 can have a different shape from the first and third pixels P1 and P3. However, a shape of the first to third pixels P1, P2 and P3 is not limited.

An area of the third pixel P3 can be greater than that of each of the first and second pixels P1 and P2, and an area of the first pixel P1 can be equal to or smaller than that of the second pixel P2. However, an area of the first to third pixels P1, P2 and P3 is not limited.

The first and third pixels P1 and P3 are alternately arranged along a first direction X. The second pixel P2 is spaced apart from a pixel column including the first and third pixel P1 and P3 in a second direction Y and arranged along the first direction X. The second direction Y crosses the first direction X. The second direction Y can be perpendicular to the first direction X.

The second to fourth signal lines SL2, SL3 and SL4 extend along the second direction Y and are spaced apart from each other in the first direction X. The second and third signal lines SL2 and SL3 overlap the first electrode 460a and are spaced apart from each other, and the fourth signal lines SL4 is positioned at one side of the second signal line SL2 and at one side of the third signal line SL3.

The each of the second and third signal lines SL2 and SL3 can be a data line DL (of FIG. 1), and each of the fourth signal lines SL4 can be a reference signal line for applying the reference signal Vre (of FIG. 2).

A first electrode 460a of a light emitting diode D (of FIG. 2) is arranged in an island shape in each of the first to third pixels P1, P2 and P3.

In addition, a step compensation pattern 480 corresponding to the first electrode 260a is disposed in each of the first to third pixels P1, P2 and P3 and under the first electrode 260a.

The step compensation pattern 480 includes an extending line portion 482 extending along the second direction Y. For example, the extending line portion 482 can extend from both ends, which is in the second direction Y, of the step compensation pattern 480 along the second direction Y.

The extending line portion 482 of the step compensation pattern 480 can be positioned between the second and third signal lines SL2 and SL3 and can act as a first signal line SL1. For example, the extending line portion 482 can be a high level signal line for applying the high level signal Vdd (of FIG. 2)

In FIG. 8, the first to third signal lines SL1, SL2 and SL3 are disposed in each of the first and third pixels P1 and P3, and the fourth signal line SL4 is disposed in the second pixel P2. However, in the light emitting diode display device 200 of the present disclosure, the arrangements of the pixels P1, P2 and SP3 and the signal lines SL1, SL2, SL3 and SL4 are not limited.

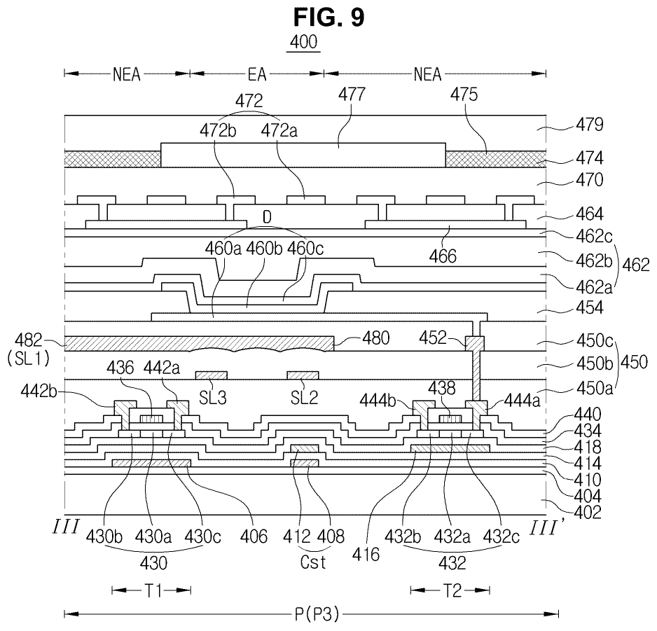

FIG. 9 is a schematic cross-sectional view illustrating a light emitting diode display device according to the fourth embodiment of the present disclosure. Particularly, FIG. 9 shows a cross-sectional view taken along the line III-III′ of FIG. 8.

Referring to FIG. 9, the light emitting diode display device 400 includes a substrate 402 including a pixel P, a pixel circuit layer disposed over the substrate 402 and including first and second transistors T1 and T2, a first insulating layer 450a disposed over the pixel circuit layer, first to third signal lines SL1, SL2 and SL3 disposed over the first insulating layer 450a, a second insulating layer 450b covering the second and third signal lines SL2 and SL3, a step compensation pattern 480 disposed on the second insulating layer 450b and used as the first signal line SL1, a third insulating layer 450c disposed on the step compensation pattern 480 and a light emitting diode D disposed on the third insulating layer 450b. The pixel circuit layer corresponds to the pixel P.

A plurality of pixels P are defined on the substrate 402. The pixel P includes an emission area EA and a non-emission area NEA. The non-emission area NEA can surround the emission area EA. The substrate 402 can be a glass substrate or a plastic substrate. In an embodiment of the present disclosure, the substrate 402 can have a triple-layered structure including a first polyimide (P1) layer, a second P1 layer and an interlayer inorganic layer between the first and second PIlayers.

A first buffer layer 404 is disposed on the substrate 402. The external moisture and/or oxygen can be blocked by the first buffer layer 404.

A first light shielding pattern 406 is disposed on the first buffer layer 404. The light from a side of the substrate 402 can be blocked by the first light shielding pattern 406.

A first capacitor electrode 408 is disposed on the first buffer layer 404. The first capacitor electrode 408 can be spaced apart from the first light shielding pattern 406.

A second buffer layer 410 is disposed over the substrate 402 to cover the first light shielding pattern 406 and the first capacitor electrode 408. The external moisture and/or oxygen can be blocked by the second buffer layer 410.

A second capacitor electrode 412 corresponding to the first capacitor electrode 408 is disposed on the second buffer layer 410. The second capacitor electrode 412 overlaps the first capacitor electrode 408. The first capacitor electrode 408, the second buffer layer 410 and the second capacitor electrode 412 constitute a storge capacitor Cst.

A third buffer layer 414 is disposed over the substrate 402 to cover the second capacitor electrode 412. The external moisture and/or oxygen can be blocked by the third buffer layer 414.

A second light shielding pattern 416 is disposed on the third buffer layer 414. The light from a side of the substrate 402 can be blocked by the second light shielding pattern 416.

A fourth buffer layer 418 is disposed over the substrate 402 to cover the second light shielding pattern 416. The external moisture and/or oxygen can be blocked by the fourth buffer layer 418.

A first semiconductor layer 430 and a second semiconductor layer 432, which is spaced apart from the first semiconductor layer 430, are disposed on the fourth buffer layer 418. The first semiconductor layer 430 corresponds to the first light shielding pattern 406, and the second semiconductor layer 432 corresponds to the second light shielding pattern 416.

Each of the first and second semiconductor layers 430 and 432 can include one of a poly-crystalline semiconductor material, an amorphous semiconductor material and an oxide semiconductor material.

In an embodiment of the present disclosure, each of the first and second semiconductor layers 430 and 432 can include the above oxide semiconductor material.

In an embodiment of the present disclosure, each of the first and second semiconductor layers 430 and 432 can include a poly-crystalline semiconductor material such as polycrystalline silicon.

In an embodiment of the present disclosure, one of the first and second semiconductor layers 430 and 432 can include the oxide semiconductor material, and the other one of the first and second semiconductor layers 430 and 432 can include the poly-crystalline semiconductor material. In this case, the first and second semiconductor layers 430 and 432 can be disposed at different layers.

The first semiconductor layer 430 includes a first channel region 430a, a first drain region 430b at one side of the first channel region 430a and a first source region 430c at the other one side of the first channel region 430a. Each of the first drain region 430b and the first source region 430c can be doped with impurities.

The second semiconductor layer 432 includes a second channel region 432a, a second drain region 432b at one side of the second channel region 432a and a second source region 432c at the other one side of the second channel region 432a. Each of the second drain region 432b and the second source region 432c can be doped with impurities.

A gate insulating layer 434 covering the first and second semiconductor layers 430 and 432 is disposed over the fourth buffer layer 418.

A first gate electrode 436 corresponding to the first channel region 430a of the first semiconductor layer 430 and a second gate electrode 438 corresponding to the second channel region 432a of the second semiconductor layer 432 are disposed on the gate insulating layer 434.

A first interlayer insulating layer 440 covering the first and second gate electrodes 436 and 438 is disposed over the gate insulating layer 434. The external moisture and/or oxygen can be blocked by the first interlayer insulating layer 440.

A first source electrode 442a, a first drain electrode 442b, a second source electrode 444a and a second drain electrode 444b spaced apart from each other are disposed on the first interlayer insulating layer 440.

The first source and drain electrodes 442a and 442b are connected to the first source and drain regions 430c and 430b of the first semiconductor layer 430 through contact holes in the first interlayer insulating layer 440 and the gate insulating layer 434, respectively. In addition, the first source electrode 442a is connected to the first capacitor electrode 408 through a contact hole in the first interlayer insulating layer 440, the gate insulating layer 434, the fourth buffer layer 418, the third buffer layer 414 and the second buffer layer 410.

The second source and drain electrodes 444a and 444b are connected to the second source and drain regions 432c and 432b of the second semiconductor layer 432 through contact holes in the first interlayer insulating layer 440 and the gate insulating layer 434, respectively. In addition, the second source electrode 444a is connected to the second capacitor electrode 412 through a contact hole in the first interlayer insulating layer 440, the gate insulating layer 434, the fourth buffer layer 418 and the third buffer layer 414.

The first semiconductor layer 430, the first gate electrode 436, the first source electrode 442a and the first drain electrode 442b constitute the first transistor T1, and the second semiconductor layer 432, the second gate electrode 438, the second source electrode 444a and the second drain electrode 444b constitute the second transistor T2. Each of the first and second transistors T1 and T2 can be a thin film transistor.

An insulating layer 450 covering the first source electrode 442a, the first drain electrode 442b, the second source electrode 444a and the second drain electrode 444b is disposed on the first interlayer insulating layer 440. Namely, the insulating layer 450 covers the first and second transistors T1 and T2.

The insulating layer 450 can include a first insulating layer 450a on the first source electrode 442a, the first drain electrode 442b, the second source electrode 444a and the second drain electrode 444b, a second insulating layer 450b on the first insulating layer 450a and a third insulating layer 450c on the second insulating layer 450b.

The second and third signal lines SL2 and SL3 are disposed on the first insulating layer 450a. The second and third signal lines SL2 and SL3 extends along the second direction Y and are spaced apart from each other in the first direction X. Each of the second and third signal lines SL2 and SL3 can be a date line DL (of FIG. 1).

The second insulating layer 450b covering the second and third signal lines SL2 and SL3 is disposed on the first insulating layer 450a.

A connection electrode 452 corresponding to the second source electrode 444a is disposed on the second insulating layer 450b. The connection electrode 452 can be connected to the second source electrode 444a through a contact hole formed in the second insulating layer 450b.

In addition, the step compensation pattern 480 is disposed on the second insulating layer 450b. The step compensation pattern 480 corresponds to and covers the second and third signal lines SL2 and SL3 and is spaced apart from the connection pattern 452.

The second and third signal lines SL2 and SL3 are disposed to correspond to the pixel P so that the second insulating layer 450b has an uneven surface. Namely, the step difference by the second and third signal lines SL2 and SL3 is reflected onto the second insulating layer 450b so that the flatness of the second insulating layer 450b is degraded.

In the light emitting diode display device 400 of the present disclosure, the step compensation pattern 480 corresponding to the second and third signal lines SL2 and SL3 covers the uneven surface of the second insulating layer 450b so that the unevenness of the second insulating layer 450b can be compensated.

An end of the step compensation pattern 480 extends along the second direction Y (of FIG. 8) to form an extending line portion 482 acting as a signal line. For example, the extending line portion 482 can be a first signal line acting as a high level signal line for applying a high level signal Vdd (of FIG. 2) and can be positioned between the second and third signal lines SL2 and SL3.

In the first direction X (of FIG. 8), the step compensation pattern 480 has a first width, and the extending line portion 482 has a second width being smaller than the first width. For example, a width of the extending line portion 482 can be substantially same as each of the second and third signal lines SL2 and SL3.

In the light emitting diode display device 400 according to the fourth embodiment of the present disclosure, the second and third signal lines SL2 and SL3 are disposed under the second insulating layer 450b, and the first signal line SL1 (e.g., the extending line portion 482), which extends from the step compensation pattern 480 and is positioned between the second and third signal lines SL2 and SL3, is disposed on the second insulating layer 450b. Namely, the first signal line SL1 is disposed at different layers from the second and third signal lines SL2 and SL3. Accordingly, a limitation to a width of the first to third signal lines SL1, SL2 and SL3 can be minimized.

In an embodiment of the present disclosure, each of the second and third signal lines SL2 and SL3 can have a first thickness, and each of the step compensation pattern 480 and extending line portion 482 can have a second thickness being greater than the first thickness.

The third insulating layer 450c is disposed on the connection electrode 452, the step compensation pattern 480 and extending line portion 482, and the first electrode 460a is disposed on the third insulating layer 450c. The first electrode 460a is connected to the connection electrode 452 through a contact hole formed in the third insulating layer 450c.

The first electrode 460a is separately formed in each pixel region P. The first electrode 460a can be an anode and can include a transparent conductive oxide (TCO) layer, which is formed of a conductive material, e.g., a transparent conductive oxide material, having a relatively high work function, and a reflective layer.

A pixel definition layer (e.g., bank) 454 is formed on the third insulating layer 450c at a boundary of the pixel region. The pixel definition layer 454 covers an edge of the first electrode 460a and has an opening to expose a center of the first electrode 460a.

The step compensation pattern 480 can have substantially the same shape. For example, the step compensation pattern 480 can have the same shape as the opening of the pixel definition layer 454. The step compensation pattern 480 can have an area being larger than the opening of the pixel definition layer 454 and smaller than the first electrode 460a.

In the light emitting diode display device 400 according to the fourth embodiment of the present disclosure, the step difference by the second and third signal lines SL2 and SL3 is compensated by the step compensation pattern 480 so that at least a portion of the first electrode 460a, e.g., the first electrode 460a in the opening of the pixel definition layer 454, has an even (e.g., flat) surface. Accordingly, the decrease of the emitting efficiency and/or the lifespan of the light emitting diode display device 400 can be minimized or prevented.

A light emitting layer 460b covering the first electrode 460a and the pixel definition layer 454 is disposed. The light emitting layer 460b contacts the first electrode 460a in the opening of the pixel definition layer 454. Namely, the light emitting layer 460b can be formed to contact an upper surface of the first electrode 460a and a side surface and an upper surface of the pixel definition layer 454.

A second electrode 460c is formed over the substrate 402 where the light emitting layer 460b is formed. The second electrode 460c covers an entire surface of the display area. The second electrode 460c can be formed of at least one of ITO, IZO, Al, Ag, Cu, Pb, magnesium (Mg), Mo, Ti and their alloy and have a single-layered structure or a multi-layered structure. The second electrode 460c can have a thin profile (small thickness) to provide a light transmittance property (or a semi-transmittance property).

The first electrode 460a, the organic light emitting layer 460b and the second electrode 460c constitute a light emitting diode D. The light emitting diode D can emit the red, green and blue light in the red, green and blue pixel region, respectively.

In the light emitting diode display device 400, the light from the light emitting layer 460b passes through the second electrode 460c to display an image. Namely, the light emitting diode display device 400 of the present disclosure is a top-emission type display device.

In an embodiment of the present disclosure, the first electrode 460a can be a transparent electrode. Namely, the first electrode 460a can have a single-layered structure of the transparent conductive oxide layer.

In this case, the step compensation pattern 480 under the first electrode 460a acts as a reflection layer to the light passing through the first electrode 460a. Accordingly, although the first electrode 460a has a single-layered structure of the transparent conductive oxide layer in the top-emission type light emitting diode display device 400, the efficiency of the light emitting diode display device 400 is not decreased.

In addition, since the first electrode 460a has a single-layered structure of the transparent conductive oxide layer, a process defect problem, which can occur in the pattern process of the first electrode 460a, can be prevented.

An encapsulation layer (or encapsulation film) 462 is formed on the second electrode 460c to prevent penetration of moisture into the light emitting diode D. The encapsulation layer 462 can include a first inorganic insulating layer 462a, an organic insulating layer 462b and a second inorganic insulating layer 462c sequentially stacked, but it is not limited thereto.

A fifth buffer layer 464 is disposed on the encapsulation layer 462 and over an entire substrate 402. The external moisture and/or oxygen can be blocked by the fifth buffer layer 464.

A bridge pattern 466 is disposed on the fifth buffer layer 464. When the fifth buffer layer 464 is omitted, the bridge pattern 466 can be disposed directly on the encapsulation layer 462.

A second interlayer insulating layer 470 disposed on the fifth buffer layer 464 and over an entire substrate 402.

A touch electrode 472 is disposed on the second interlayer insulating layer 470. The touch electrode includes a first touch electrode 472a and a second touch electrode 472b. The first touch electrodes 472a are spaced apart from each other, and the second touch electrodes 472b is disposed between the first touch electrodes 472b. The second touch electrode 472b is connected to the bridge pattern 466 through a contact hole formed in the second interlayer insulating layer 470.

A first protection layer 474 is disposed on the first and second touch electrodes 472a and 472b and over an entire substrate 402.

A black matrix 475 is disposed on the first protection layer 474. The black matrix 475 is disposed in a boundary of the pixel region P and has an opening in correspondence to the light emitting diode D. Namely, the opening of the black matrix 475 can correspond to the opening of the pixel definition layer 454.

The opening of the black matrix 475 can have an area being larger than the opening of the pixel definition layer 454. For example, the pixel definition layer 454 can have a first width, and the black matrix 475 can have a second width being smaller than the first width. When the area of the opening of the black matrix 475 is equal to or smaller than that of the opening of the pixel definition layer 454, the viewing angle of the light emitting diode display device 400 can be decreased.

A color filter layer 477 corresponding to the opening of the black matrix 475 is disposed on the first protection layer 474. The color filter layer 477 can include a red color filter corresponding to the red pixel, a green color filter corresponding to the green pixel and a blue color filter corresponding to the blue pixel.

A second protection layer 479 is disposed on the black matrix 475 and the color filter layer 477 and over an entire substrate 402.

In the light emitting diode display device 400 according to the fourth embodiment of the present disclosure, since the first to third signal lines SL1, SL2 and SL3 are disposed to cross the pixel P, a limitation to a width of the first to third signal lines SL1, SL2 and SL3 can be minimized.

In addition, the light emitting diode display device 400 includes the step compensation pattern 480 covering the second and third signal lines SL2 and SL3 and disposed under the first electrode 460a, the flatness of the first electrode 460a can be improved. Accordingly, the decrease of the emitting efficiency and/or the lifespan of the light emitting diode display device 400 resulted from the unevenness of the first electrode 460a can be minimized or prevented.

Moreover, the second and third signal lines SL2 and SL3 are disposed under the second insulating layer 450b, and the first signal line SL1 (e.g., the extending line portion 482), which extends from the step compensation pattern 480 and is positioned between the second and third signal lines SL2 and SL3, is disposed on the second insulating layer 450b. Accordingly, a limitation to a width of the first to third signal lines SL1, SL2 and SL3 can be further minimized.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. A light emitting diode display device, comprising:
a substrate including a pixel, the pixel including an emission area and a non-emission area;
a first insulating layer disposed on the substrate;
a step compensation pattern disposed on the first insulating layer and corresponding to the emission area;
a second insulating layer covering the step compensation pattern;
a first electrode disposed on the second insulating layer and corresponding to the step compensation pattern; and
a pixel definition layer disposed on the second insulating layer and in the non-emission area, the pixel definition layer covering an edge of the first electrode and having an opening in correspondence to a center of the first electrode,
wherein the step compensation pattern has a shape being same as or substantially same as a shape of the opening of the pixel definition layer.

2. The light emitting diode display device according to claim 1, wherein a size of an area of the step compensation pattern is greater than a size of an area of the opening of the pixel definition layer and is smaller than a size of an area of the first electrode.

3. The light emitting diode display device according to claim 1, wherein the step compensation pattern has an island shape.

4. The light emitting diode display device according to claim 1, further comprising:
a light emitting layer disposed on the first electrode and in the opening of the pixel definition layer; and
a second electrode covering the light emitting layer in the opening of the pixel definition layer and the pixel definition layer.

5. The light emitting diode display device according to claim 4, wherein the step compensation pattern includes an extending portion, and
wherein the extending portion of step compensation pattern extends from at least one end of the step compensation pattern to the pixel definition layer and protrudes from the first electrode.

6. The light emitting diode display device according to claim 5, wherein the second electrode is electrically connected to the extending portion of the step compensation pattern.

7. The light emitting diode display device according to claim 5, wherein the pixel definition layer and the second insulating layer include a contact hole corresponding to the extending portion of the step compensation pattern, and the second electrode is connected to the extending portion of the step compensation pattern through the contact hole.

8. The light emitting diode display device according to claim 1, wherein the step compensation pattern includes an extending line portion extending along a first direction.

9. The light emitting diode display device according to claim 8, further comprising:
a third insulating layer between the substrate and the first insulating layer; and
a first signal line disposed on the third insulating layer and extending along the first direction,
wherein the extending line portion and the first signal line are spaced apart from each other in a second direction, and the second direction crosses the first direction.

10. The light emitting diode display device according to claim 9, further comprising:
a second signal line disposed on the third insulating layer and extending along the first direction,
wherein the extending line portion and the first signal line are spaced apart from each other in the second direction, and the extending line portion is positioned between the first and second signal lines.

11. The light emitting diode display device according to claim 9, wherein a thickness of the step compensation pattern is greater than a thickness of the first signal line.

12. The light emitting diode display device according to claim 8, wherein in a second direction being perpendicular to the first direction, the step compensation pattern has a first width, and the extending line portion of the step compensation pattern has a second width, and
wherein the second width is smaller than the first width.

13. The light emitting diode display device according to claim 1, wherein the first electrode has a single-layered structure of a transparent conductive oxide layer, and
wherein the step compensation pattern acts as a reflective layer to a light through the first electrode.

14. The light emitting diode display device according to claim 13, further comprising:
a light emitting layer on the first electrode and in the opening of the pixel definition layer;
a second electrode covering the light emitting layer in the opening of the pixel definition layer and the pixel definition layer; and
a color filter layer on the second electrode.

15. The light emitting diode display device according to claim 1, wherein the step compensation pattern has an uneven bottom surface and an even top surface.

16. The light emitting diode display device according to claim 1, further comprising:
a transistor including a semiconductor layer, a gate electrode, a source electrode and a drain electrode,
wherein the first electrode is connected to the drain electrode, and the semiconductor layer includes one of a poly-crystalline semiconductor material, an amorphous semiconductor material and an oxide semiconductor material.

17. The light emitting diode display device according to claim 1, further comprising:
a third insulating layer between the substrate and the first insulating layer; and
a signal line disposed on the third insulating layer,
wherein the step compensation pattern corresponds to the signal line.

18. The light emitting diode display device according to claim 17, wherein a thickness of the step compensation pattern is greater than a thickness of the signal line.

19. The light emitting diode display device according to claim 17, wherein the first insulating layer has an uneven top surface, and the step compensation patter has an even top surface.

20. A display panel, comprising:
a substrate including a pixel, the pixel including an emission area and a non-emission area;
a first insulating layer disposed on the substrate;
a step compensation pattern disposed on the first insulating layer and corresponding to the emission area;
a second insulating layer covering the step compensation pattern;
a first electrode disposed on the second insulating layer and corresponding to the step compensation pattern; and
a pixel definition layer disposed on the second insulating layer and in the non-emission area, the pixel definition layer covering an edge of the first electrode and having an opening in correspondence to a center of the first electrode,
wherein the step compensation pattern has a shape being same as or substantially same as the opening of the pixel definition layer.

21. The display panel according to claim 20, further comprising:
a third insulating layer between the substrate and the first insulating layer; and
a plurality of signal lines disposed on the third insulating layer,
wherein the step compensation pattern corresponds to the plurality of signal lines.

22. The display panel according to claim 21, wherein the first insulating layer has an uneven top surface generated due to step differences of the plurality of signal lines, and
wherein the step compensation pattern compensates for the uneven top surface of the first insulating layer and has an uneven bottom surface and an even top surface.

23. The display panel according to claim 20, further comprising:
a light emitting layer on the first electrode and in the opening of the pixel definition layer; and
a second electrode covering the light emitting layer in the opening of the pixel definition layer and the pixel definition layer.

24. The display panel according to claim 23, wherein the step compensation pattern includes an extending portion,
wherein the extending portion extends from at least one end of the step compensation pattern to the pixel definition layer and protrudes from the first electrode, and
wherein the second electrode is electrically connected to the extending portion of the step compensation pattern.

25. The display panel according to claim 20, wherein the first electrode has a single-layered structure of a transparent conductive oxide layer, and
wherein the step compensation pattern acts as a reflective layer to a light through the first electrode.

26. The display panel according to claim 20, further comprising:
a third insulating layer between the substrate and the first insulating layer;
a first signal line disposed on the third insulating layer and extending along the first direction; and
a second signal line disposed on the third insulating layer and extending along the first direction,
wherein the first signal line and the second signal line are spaced apart from each other in a second direction, and the second direction crosses the first direction, and
wherein the step compensation pattern includes an extending line portion extending along the first direction, and the extending line portion is positioned between the first and second signal lines.

27. The display panel according to claim 26, wherein in the second direction, the step compensation pattern has a first width, and the extending line portion of the step compensation pattern has a second width, and
wherein the second width is smaller than the first width, and the second width is equal to a width of at least one of the first and second signal lines.
